(19) United States
(12) Patent Application Publication
(10) Pub. No.: US 2024/0162137 A1
(43) Pub. Date: May 16, 2024

(54) SEMICONDUCTOR DEVICE AND METHOD OF MANUFACTURING THE SAME

(71) Applicant: Renesas Electronics Corporation, Tokyo (JP)

(72) Inventors: Yuki SUGIYAMA, Tokyo (JP); Eiji HIRAIWA, Tokyo (JP); Akira MITSUIKI, Tokyo (JP)

(21) Appl. No.: 18/510,635

(22) Filed: Nov. 15, 2023

(30) Foreign Application Priority Data
Nov. 16, 2022 (JP) 2022-183546

(51) Int. Cl. H01L 23/522

(52) U.S. Cl. CPC H01L 23/5223; H01L 28/60

(57) ABSTRACT

A manufacturing method of a semiconductor device includes: depositing a first conductor film, a dielectric film, and a second conductor film in this order in a MIM region and a wiring region; selectively removing the second conductor film, thereby forming an upper electrode of a capacitor element from the second conductor film; selectively removing the exposed dielectric film, thereby exposing the first conductor film in the wiring region and forming a dielectric layer having a flange portion remaining so as to protrude outward from a region under the upper electrode in the MIM region; and selectively removing the first conductor film, thereby forming a lower electrode of the capacitor element from the first conductor film and forming a wiring pattern from the first conductor film of which the upper surface is exposed in the wiring region.

### CROSS-REFERENCE TO RELATED APPLICATIONS

The disclosure of Japanese Patent Application No. 2022-183546 filed on Nov. 16, 2022, including the specification, drawings and abstract is incorporated herein by reference in its entirety.

### BACKGROUND

The present disclosure relates to a semiconductor device and a method of manufacturing the same.

There are disclosed techniques listed below. [Patent Document 1] Japanese Unexamined Patent Application Publication No. 2005-191182

In a semiconductor device described in Patent Document 1, a lower electrode of a MIM capacitor element and a wiring pattern formed of at least one wiring are formed by patterning one conductive layer. A capacitor dielectric film of the MIM capacitor element is formed not only on the lower electrode but also on the wiring pattern in a wiring region.

In a manufacturing method of the semiconductor device, after a lower conductor film, the capacitor dielectric film, and an upper conductor film are formed in this order, the upper conductor film is etched using a mask to form an upper electrode, and the capacitor dielectric film is further continuously etched to the middle using the mask. Thereafter, the remaining film of the capacitor dielectric film and the lower conductor film are etched using a mask covering the side surfaces of the upper electrode and the capacitor dielectric film, the capacitor dielectric film, the lower electrode, and the wiring pattern are simultaneously formed. Accordingly, in the semiconductor device, since the conductive deposits do not adhere to the side surfaces of the upper electrode and the capacitor dielectric film in the etching process, a decrease in the breakdown voltage is suppressed.

### SUMMARY

In recent years, miniaturization of wiring patterns has been advanced. However, in the semiconductor device in which the capacitor dielectric film and the wiring pattern are continuously processed using a single mask such the semiconductor device described in Patent Document 1, it is difficult to miniaturize the wiring pattern.

In the semiconductor device described in Patent Document 1, a thickness of the remaining film of the capacitor dielectric film may vary. If the remaining film of the capacitor dielectric film is thick, a dielectric film filling between adjacent wirings is not properly formed, and voids may be formed in the dielectric film. On the other hand, if the remaining film of the capacitor dielectric film is thin, an upper edge of the wiring is exposed when forming a dielectric film filling between adjacent wirings, and the material configuring the exposed portion of the wiring may be re-spattered between wirings and short-circuited between wiring.

Other objects and novel features will become apparent from the description of this specification and the accompanying drawings.

According to the present disclosure, a manufacturing method of a semiconductor device is a manufacturing method of a semiconductor device including a first region where a capacitor element is formed and a second region where a wiring pattern is formed. The manufacturing method of the semiconductor device includes: depositing a first conductor film, a dielectric film, and a second conductor film in this order in the first region and the second region; and forming an upper electrode of the capacitor element from the remaining second conductor film by selectively removing the second conductor film. Further, the manufacturing method of the semiconductor device includes: selectively removing the exposed dielectric film, thereby exposing the first conductor film in the second region and forming a dielectric layer having a flange portion in the first region; and selectively removing the first conductor film, thereby forming a wiring pattern from the first conductor film of which an upper surface is exposed in the second region.

According to the present disclosure, a semiconductor device includes a MIM capacitor element, a wiring pattern, and an interlayer dielectric film formed on the MIM capacitor element and the wiring pattern. The MIM capacitor element includes a lower electrode, a dielectric layer formed on the lower electrode, and an upper electrode formed on the dielectric layer. The dielectric layer has a flange portion remaining so as to protrude outward from a region under the upper electrode. An upper surface of the wiring pattern is in contact with the interlayer dielectric film.

According to the present disclosure, a semiconductor device in which the wiring pattern can be miniaturized as compared with the conventional semiconductor device can be provided while suppressing a decrease in the breakdown voltage.

### BRIEF DESCRIPTION OF THE DRAWINGS

FIG. 1 is a partially enlarged cross-sectional view showing a semiconductor device according to a first embodiment.

FIG. 2 is a partially enlarged plan view as viewed from the arrow II-II in FIG. 1.

FIG. 3 is a partially enlarged cross-sectional view showing one step of a manufacturing method of the semiconductor device according to the first embodiment.

FIG. 4 is a cross-sectional view showing one step after the step shown in FIG. 3 in the manufacturing method of the semiconductor device according to the first embodiment.

FIG. 5 is a cross-sectional view showing one step after the step shown in FIG. 4 in the manufacturing method of the semiconductor device according to the first embodiment.

FIG. 6 is a cross-sectional view showing one step after the step shown in FIG. 5 in the manufacturing method of the semiconductor device according to the first embodiment.

FIG. 7 is a cross-sectional view showing one step after the step shown in FIG. 6 in the manufacturing method of the semiconductor device according to the first embodiment.

FIG. 8 is a cross-sectional view showing one step after the step shown in FIG. 7 in the manufacturing method of the semiconductor device according to the first embodiment.

FIG. 9 is a partially enlarged cross-sectional view showing a semiconductor device according to a second embodiment.

FIG. 10 is a partially enlarged plan view as viewed from the arrow X-X in FIG. 9.

FIG. 11 is a partially enlarged cross-sectional view showing one step of a manufacturing method of the semiconductor device according to the second embodiment.

FIG. 12 is a cross-sectional view showing one step after the step shown in FIG. 11 in the manufacturing method of the semiconductor device according to the second embodiment.

FIG. 13 is a partially enlarged cross-sectional view showing a semiconductor device according to a third embodiment.

FIG. 14 is a partially enlarged cross-sectional view showing one step of a manufacturing method of the semiconductor device according to the third embodiment.

FIG. 15 is a cross-sectional view showing one step after the step shown in FIG. 14 in the manufacturing method of the semiconductor device according to the third embodiment.

FIG. 16 is a cross-sectional view showing one step after the step shown in FIG. 15 in the manufacturing method of the semiconductor device according to the third embodiment.

FIG. 17 is a cross-sectional view showing one step after the step shown in FIG. 16 in the manufacturing method of the semiconductor device according to the third embodiment.

FIG. 18 is a cross-sectional view showing one step after the step shown in FIG. 17 in the manufacturing method of the semiconductor device according to the third embodiment.

FIG. 19 is a cross-sectional view showing one step after the step shown in FIG. 18 in the manufacturing method of the semiconductor device according to the third embodiment.

FIG. 20 is a partially enlarged cross-sectional view showing a modified example of the semiconductor device according to the second embodiment.

FIG. 21 is a partially enlarged cross-sectional view showing one step of the manufacturing method of the semiconductor device shown in FIG. 20.

FIG. 22 is a cross-sectional view showing one step after the step shown in FIG. 21 in the manufacturing method of the semiconductor device shown in FIG. 20.

FIG. 23 is a cross-sectional view showing one step after the step shown in FIG. 22 in the manufacturing method of the semiconductor device shown in FIG. 20.

FIG. 24 is a diagram for explaining a problem that may occur when a thickness of a dielectric film remaining in a wiring region is thin in a manufacturing method of a semiconductor device according to a comparative example.

### DETAILED DESCRIPTION

Hereinafter, embodiments will be described with reference to the drawings. In the following drawings, the same or corresponding parts are denoted by the same reference numerals, and the description thereof will not be repeated. Hereinafter, for convenience of explanation, a first direction X, a second direction Y, and a third direction Z orthogonal to one another are used.

When the terms “orthogonal,” “along,” “congruent,” “equivalent,” and the like are used in the present embodiment to represent relative relationships such as geometric sentences and relative relationships such as position, magnitude, and direction, the terms allow for manufacturing errors or slight variations.

### First Embodiment

Structure of Semiconductor Device

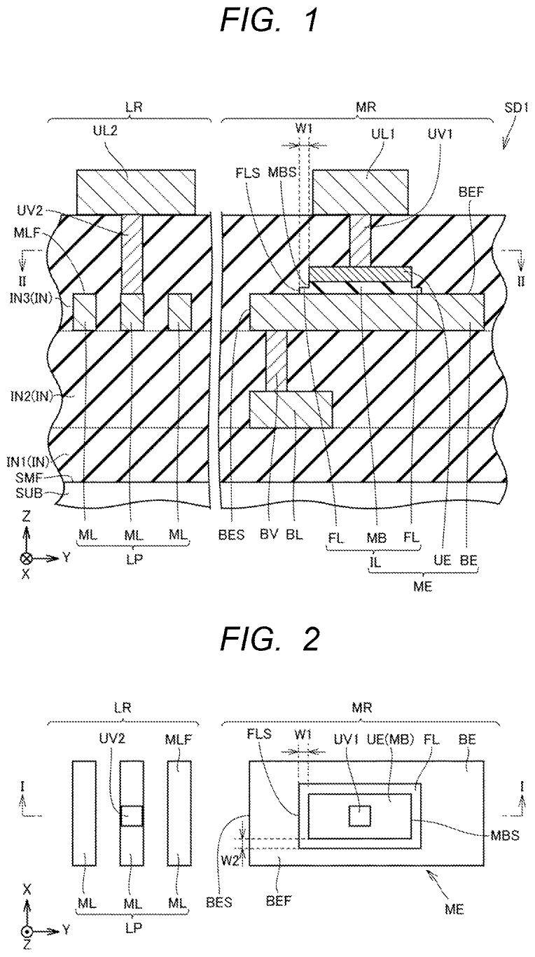

As shown in FIG. 1, a semiconductor device SD1 according to the first embodiment is, for example, a microcontroller. The semiconductor device SD1 is, for example, in a chip state and has a semiconductor substrate SUB. The semiconductor substrate SUB has the main surface MSF. The main surface MSF extends along the first direction X and the second direction Y and is orthogonal to the third direction Z.

The semiconductor device SD1 of the present embodiment is not limited to a semiconductor chip, and may be in a wafer state prior to being divided into semiconductor chips, or may be in a packaged state in which the semiconductor chip is sealed with a sealing resin. In the present specification, the term “plan view” means a viewpoint viewed from the third direction Z orthogonal to a main surface SMF of the semiconductor substrate SUB. In the present specification, the term “lower” or “lower portion” means a side closer to the semiconductor substrate SUB than the comparative object in the third direction Z, and the term “upper” or “upper portion” means a side opposite to the comparative object.

As shown in FIG. 1, at least a MIM region MR (first region) and a wiring region LR (second region) are formed on the main surface SMF of the semiconductor substrate SUB. At least one MIM capacitor element ME is formed in the MIM region MR. The MIM capacitor element ME is configured by a lower electrode BE, a dielectric layer IL, and an upper electrode UE. A wiring pattern LP including a plurality of wirings ML is formed in the wiring region LR. The MIM capacitor element ME and the wiring pattern LP are buried in a dielectric film IN. The dielectric film IN includes a first interlayer dielectric film IN1, a second interlayer dielectric film IN2, and a third interlayer dielectric film IN3, which are sequentially laminated from the semiconductor substrate SUB in the third direction Z. The second interlayer dielectric film IN2 is disposed opposite to the semiconductor substrate SUB with respect to the first interlayer dielectric film IN1. The third interlayer dielectric film IN3 is disposed opposite to the semiconductor substrate SUB with respect to the second interlayer dielectric film IN2. That is, the first interlayer dielectric film IN1 is disposed on the semiconductor substrate SUB, the second interlayer dielectric film IN2 is disposed on the first interlayer dielectric film IN1, and the third interlayer dielectric film IN3 is disposed on the second interlayer dielectric film IN2. Each of the lower electrode BE of the MIM capacitor element ME and the wiring pattern LP in the wiring region LR is formed by patterning one conductive film formed on an upper surface of the second interlayer dielectric film IN2. The third interlayer dielectric film IN3 is formed on the MIM capacitor element ME and the wiring pattern LP. The third interlayer dielectric film IN3 is in contact with a surface of the MIM capacitor element ME and an upper surface of the wiring pattern LP. In the drawings other than FIG. 1, illustration of the dielectric film IN is omitted.

A plurality of MIM capacitor elements ME may be formed in the MIM region MR. The lower electrode BE of each of the plurality of MIM capacitor elements ME may be electrically connected in parallel to each other. The lower electrode BE of each of the plurality of MIM capacitor elements ME may be formed of a single conductive film. The wiring pattern LP formed of at least one wiring ML may be formed in the wiring region LR. The wiring region LR is disposed side by side with the MIM region MR in the second direction Y, for example, but may be disposed side by side with the MIM region MR in the first direction X.

### Configuration of MIM Capacitor Element

As shown in FIG. 1 and FIG. 2, the dielectric layer IL of the MIM capacitor element ME is formed on a portion of the upper surface of the lower electrode BE. From a different point of view, the upper surface BEF of the lower electrode BE has a region being in contact with the dielectric layer IL and a region being not in contact with the dielectric layer IL. A region of the upper surface of the lower electrode BE that is not in contact with the dielectric layer IL is in contact with the third interlayer dielectric film IN3.

As shown in FIG. 1 and FIG. 2, the dielectric layer IL has the body portion MB and a flange portion FL.

As shown in FIG. 1, the body portion MB is sandwiched between the upper electrode UE and the lower electrode BE in the third direction Z. The body portion MB has an upper surface being in contact with the lower surface of the upper electrode UE, a lower surface being in contact with the lower electrode BE, and the side end surface MBS being in contact with the third interlayer dielectric film IN3. The side end surface MBS of the body portion MB is continuous with the side end surface of the upper electrode UE. The upper end of the side end surface MBS of the body portion MB is connected to the lower end of the side end surface of the upper electrode UE and the outer edge of the upper surface of the body portion.

As shown in FIG. 1 and FIG. 2, the flange portion FL protrudes outward from the side end surface of the upper electrode UE and the side end surface MBS of the body portion MB. The flange portion FL is formed so as to surround the upper electrode UE and the body portion MB in plan view. The flange portion FL has an upper surface and a side end surface FLS being in contact with the third interlayer dielectric film IN3, and a lower surface being in contact with the lower electrode BE. A width of the flange portion FL is defined as a distance between the side end surface FLS of the flange portion FL and the side end surface MBS of the body portion MB. Preferably, the smallest width of the flange portion FL is 50 nm or more. The width W1 of the flange portion FL in the first direction X is equal to the width W2 of the flange portion in the second direction Y, for example. That is, the side end surface FLS of the flange portion FL is spaced apart from the side end surface of the upper electrode UE in the first direction X and the second direction Y. The width of the flange portion FL in the first direction X may be different from the width of the flange portion FL in the second direction Y, for example. The flange portion FL is thinner than the body portion MB, for example. The thickness of the flange portion FL may be equal to the thickness of the body portion MB. The thickness of the flange portion FL depends on the presence or absence of the overetching process in the upper electrode UE forming step in the manufacturing method of the semiconductor device SD1 to be described later, and the condition when the overetching process is performed.

As shown in FIG. 2, the planar shape of the upper electrode UE is, for example, rectangular in plan view. The planar shape of each of the body portion MB and the flange portion FL of the dielectric layer IL is, for example, rectangular. The planar shape of the lower electrode BE is, for example, rectangular. The planar shape of each of the upper electrode UE, the body portion MB and the flange portion FL of the dielectric layer IL, and the lower electrode BE may be any shapes.

As shown in FIG. 1, the lower electrode BE is connected to a first lead-out wiring BL via a first via-plug BV. The first lead-out wiring BL is disposed between the main surface SMF of the semiconductor substrate SUB and the lower surface of the lower electrode BE. The first lead-out wiring BL is formed on the upper surface of the first interlayer dielectric film IN1. The first via-plug BV penetrates through the second interlayer dielectric film IN2 that separates the upper surface of the first lead-out wiring BL from the lower surface of the lower electrode BE.

As shown in FIG. 1, the upper electrode UE is connected to a second lead-out wiring UL1 via a second via-plug UV1. The second lead-out wiring UL1 is formed on the upper surface of the third interlayer dielectric film IN3. The second via-plug UV1 penetrates through the third interlayer dielectric film IN3 that separates the upper surface of the upper electrode UE from the lower surface of the first lead-out wiring UL1.

As shown in FIG. 2, in plan view, the second via-plug UV1 is formed so as to overlap with the center of the upper electrode UE.

A material configuring the lower electrode BE may include, for example, aluminum (Al). The lower electrode BE is, for example, a laminated body in which a Ti layer made of titanium (Ti), a TiN layer made of titanium nitride (TiN), an Al layer made of Al, and a TiN layer are laminated in this order from the lower side in the third direction Z. A material configuring the upper electrode UE may include, for example, titanium nitride (TiN). The upper electrode UE is configured by, for example, only TiN layer.

A material configuring the dielectric layer IL may include at least one selected from the group consisting of silicon oxide (SiO₂), silicon oxynitride (SiON), and silicon nitride (SiN).

The thickness of the lower electrode BE is greater than the thickness of each of the upper electrode UE and the dielectric layer IL. The thickness of the upper electrode UE is 50 nm or more. The thickness of the upper electrode UE is typically 80 nm.

Materials configuring the first lead-out wiring BL and the second lead-out wiring UL1 include, for example, Al. The first lead-out wiring BL and the second lead-out wiring UL1 are, for example, laminated bodies configured by a Ti layer, a TiN layer, an Al layer, and a TiN layer laminated in this order from the lower side in the third direction Z, similarly to the lower electrode BE. A material configuring each of the first via-plug BV and the second via-plug UV1 includes tungsten (W), for example.

A material configuring the first interlayer dielectric film IN1, the second interlayer dielectric film IN2, and the third interlayer dielectric film IN3 includes, for example, SiO₂.

### Configuration of Wiring Pattern

As shown in FIG. 1 and FIG. 2, the wiring pattern LP includes the plurality of wirings ML spaced apart from each other in the second direction Y. The second interlayer dielectric film IN2 is buried between the plurality of wirings ML. Each upper surface of the plurality of wirings ML is in contact with the third interlayer dielectric film IN3. Each of the plurality of wirings ML is not electrically connected to each other, for example.

As shown in FIG. 1, one wiring ML is connected to a third lead-out wiring UL2 via a third via-plug UV2. Although not shown in FIG. 1, other wirings ML are also connected to a lead-out wiring (not shown) via a via-plug (not shown). The third lead-out wiring UL2 is formed on the upper surface of the third interlayer dielectric film IN3. The third via-plug UV2 penetrates through the third interlayer dielectric film IN3 separating the upper surface of the wiring ML and the lower surface of the third lead-out wiring UL2.

The distance between the plurality of wirings ML in the second direction Y is, for example, equal to or less than the thickness of each of the plurality of wirings ML.

The material configuring each of the plurality of wirings ML is the same as the material configuring the lower electrode BE. The material configuring the third lead-out wiring UL2 is, for example, the same as the material configuring the second lead-out wiring UL1. The material configuring the third via-plug UV2 is, for example, the same as the material configuring the second via-plug UV1.

### Manufacturing Method of Semiconductor Device

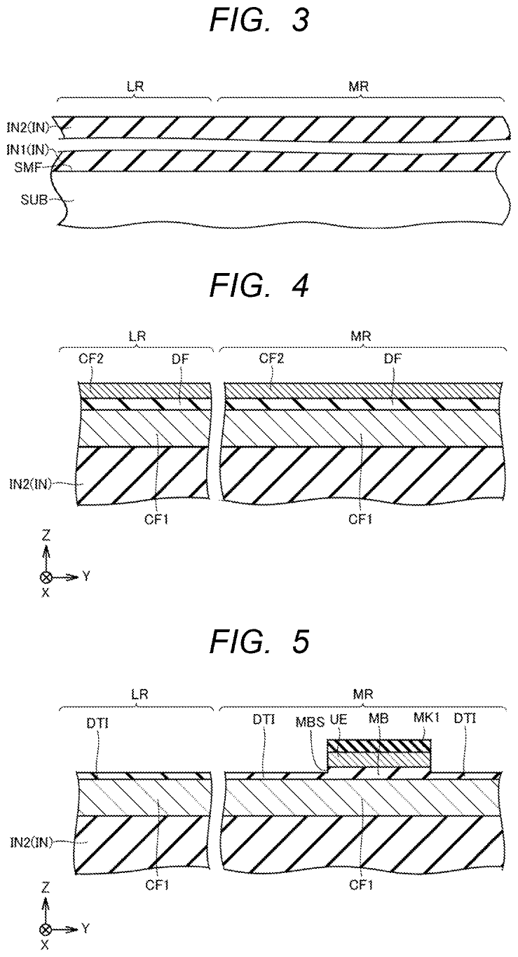

Next, referring to FIG. 3 to FIG. 7, the manufacturing method of the semiconductor device SD1 according to the first embodiment will be described. In FIG. 4 to FIG. 7, the semiconductor substrate SUB, the dielectric film IN, the first lead-out wiring BL, and the first via-plug BV are not shown.

First, as shown in FIG. 3, the semiconductor substrate SUB is prepared. In the MIM region MR and the wiring region LR, the first interlayer dielectric film IN1 and the second interlayer dielectric film IN2 are formed on the main surface SMF of the semiconductor substrate SUB. Although not shown, the first lead-out wiring BL and the first via-plug BV are formed under the second interlayer dielectric film IN2. In addition, although not shown, any element configuration (for example, a transistor) included in the semiconductor device SD1 may be formed on the semiconductor substrate SUB prepared in this step. A method of forming such a semiconductor substrate may be performed by a conventionally known method, and therefore will not be described here.

Second, as shown in FIG. 4, a first conductor film CF1, a dielectric film DF, and a second conductor film CF2 are formed on the upper surface of the second interlayer dielectric film IN2. The first conductor film CF1, the dielectric film DF, and the second conductor film CF2 are continuously formed from the lower side to the upper side in this order. The method of forming the first conductor film CF1, the dielectric film DF, and the second conductor film CF2 is not particularly limited, but is, for example, a sputtering method.

Third, as shown in FIG. 5, the upper electrode UE is formed of the second conductor film CF2. Further, the body portion MB and a thin portion DTI thinner than the body portion MB are formed in the dielectric film DF.

Specifically, a first mask MK1 is formed on the upper surface of the second conductor film CF2. The first mask MK1 is, for example, a resist mask formed by photolithography. The first mask MK1 is formed only on the main surface SMF of the semiconductor substrate SUB in the MIM region MR. Next, the second conductor film CF2 is patterned by a dry etching method or the like using the first mask MK1. This patterning process is performed so that a residue of the second conductor film CF2 does not generate in the region from which the second conductor film CF2 is to be removed. For example, the patterning process includes an overetching process. The thickness of the portion of the dielectric film DF exposed from the upper electrode UE in plan view is reduced. In this way, the upper electrode UE is formed. Further, in the dielectric film DF, the body portion MB sandwiched between the upper electrode UE and the first conductor film CF1 and the thin portion DTI exposed from the upper electrode UE and thinner than the body portion MB in plan view are formed. The body portion MB is not processed after this step. The side end surface MBS is formed on the body portion MB. In the present patterning process, the process of preventing the residue from being generated is not limited to the overetching process. That is, in the present patterning process, the overetching process is not essential. When the overetching process is not performed, the dielectric film DF is not etched, and thus the thin portion DTI is not formed. That is, the thickness of the portion of the dielectric film DF exposed from the upper electrode UE in plan view is equal to the thickness of the body portion MB. In the semiconductor device SD1, the thickness of the flange portion FL is equal to the thickness of the body portion MB.

The body portion MB and the thin portion DTI are formed by, for example, an overetching process using the first mask MK1. The thin portion DTI is formed so as to surround the upper electrode UE and the body portion MB in plan view. After the body portion MB and the thin portion DTI are formed, the first mask MK1 is removed from the upper electrode UE.

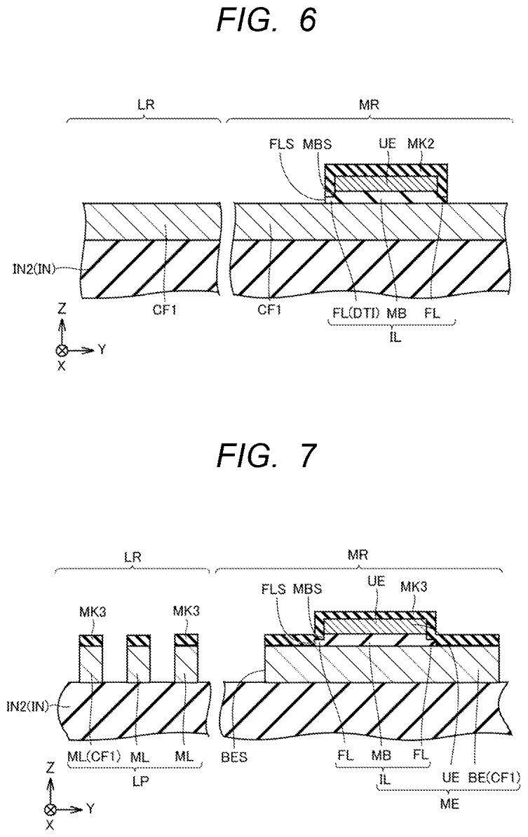

Fourth, as shown in FIG. 6, the dielectric layer IL is formed from the dielectric film DF. Specifically, a second mask MK2 is formed on a portion of the thin portion DTI so as to cover the side end surface of the upper electrode UE and the side end surface MBS of the body portion MB. The second mask MK2 is, for example, a resist mask formed by photolithography. The second mask MK2 is not formed on the main surface SMF of the semiconductor substrate SUB in the wiring region LR. The second mask MK2 is formed only on the main surface SMF of the semiconductor substrate SUB in the MIM region MR, for example.

Next, the thin portion DTI of the dielectric film DF is patterned by a dry etching method or the like using the second mask MK2. Thus, the flange portion FL is formed from the thin portion DTI. In this manner, the dielectric layer IL including the body portion MB and the flange portion FL is formed from the dielectric film DF. After the flange portion FL is formed, the second mask MK2 is removed from the upper electrode UE and the dielectric layer IL.

Fifth, as shown in FIG. 7, the lower electrode BE and the wiring pattern LP are formed from the first conductor film CF1. Specifically, a third mask MK3 is formed on a portion of the first conductor film CF1 in each of the MIM region MR and the wiring region LR. In the MIM region MR, the third mask MK3 is formed so as to cover the side end surface of the upper electrode UE, the side end surface MBS of the body portion MB, and the side end surface FLS of the flange portion FL. The thickness of the third mask MK3 may be set to be thin as long as the third mask MK3 is appropriately held until the wiring pattern LP and the lower electrode BE are processed. The third mask MK3 is, for example, a resist mask formed by photolithography. Next, the first conductor film CF1 is patterned by a dry etching method or the like using the third mask MK3. Thus, in the MIM region MR, the lower electrode BE is formed from the first conductor film CF1. At the same time, in the wiring region LR, the wiring pattern LP is formed from the first conductor film CF1. After the lower electrode BE and the wiring pattern LP are formed, the third mask MK3 is removed from above them. As a result, the MIM capacitor element ME is formed in the MIM region MR, and the wiring pattern LP is formed in the wiring region LR.

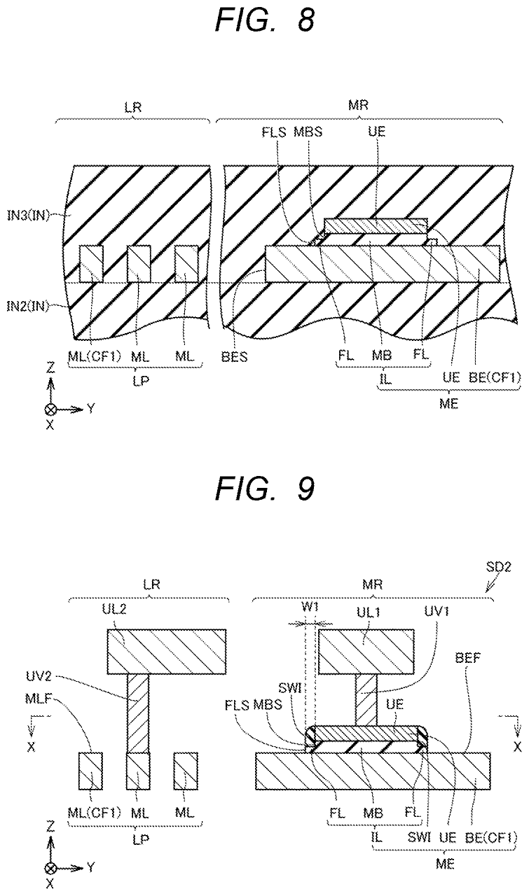

Sixth, as shown in FIG. 8, the third interlayer dielectric film IN3 is formed so as to cover the MIM capacitor element ME and the wiring pattern LP. The third interlayer dielectric film IN3 is formed by removing a part of the interlayer dielectric film formed by an HDP-CVD (High Density Plasma Chemical Vapor Deposition) method by a CMP (Chemical Mechanical Polishing) method, for example. Thereafter, the second via-plug UV1, the third via-plug UV2, the second lead-out wiring UL1 and the third lead-out wiring UL2 are formed. A method of forming each of the third interlayer dielectric film IN3, the second via-plug UV1, the third via-plug UV2, the second lead-out wiring UL1 and the third lead-out wiring UL2 may be performed by a conventionally known method, and therefore will not be described here. Thus, the semiconductor device SD1 is manufactured.

### Effects of Semiconductor Device

The effects of the semiconductor device SD1 will be described based on the comparison with the comparative example. The semiconductor device according to the comparative example has the same configuration as that of the semiconductor device according to Patent Document 1, and the dielectric layer of the MIM capacitor element is formed on the entire upper surface of each of the lower electrode in the MIM region and the wiring pattern in the wiring region. For this reason, when the wiring pattern is miniaturized in the comparative example, the mask used to simultaneously form the dielectric layer, the wiring pattern, and the lower electrode in the manufacturing method may not remain until the process of the wiring pattern is completed, and the defect of the shape of the wiring pattern may occur. The defect of the shape of the wiring pattern that occurs here appears, in particular, as a defect of the cross-sectional shape orthogonal to the extension direction of the wiring pattern. From the viewpoint of suppressing the generation of the defect of the shape of the wiring pattern, in the comparative example, the thinning of the mask is limited, and the miniaturization of the wiring pattern is also limited.

On the other hand, in the semiconductor device SD1, the dielectric layer IL is not formed on the wiring pattern LP. Therefore, in the manufacturing method of the semiconductor device SD1, the thickness of the third mask MK3 to form the wiring pattern LP and the lower electrode BE may be set to be thinner than the mask used to process the wiring pattern in the manufacturing method of the comparative example. The thickness of the third mask MK3 may be set to be as thin as possible so long as the third mask MK3 can be held until processing of the wiring pattern LP and the lower electrode BE is completed. Consequently, the wiring pattern LP of the semiconductor device SD1 can be miniaturized compared with the wiring pattern of the comparative example.

In the semiconductor device SD1, the dielectric layer IL includes the body portion MB sandwiched between the upper electrode UE and the lower electrode BE, and the flange portion FL surrounding the upper electrode UE and the body portion MB in plan view. In the manufacturing method of the semiconductor device SD1, when a portion of the thin portion DTI of the dielectric film DF is etched to form the flange portion FL, the conductive deposits do not adhere to the side surface of each of the upper electrode UE of the MIM capacitor element ME and the dielectric layer IL. Therefore, in the semiconductor device SD1, a decrease in the breakdown voltage of the MIM capacitor element MR is suppressed and the reliability of the semiconductor device SD1 is higher than the semiconductor device in which the flange portion is not formed in the MIM region MR.

### Second Embodiment

As shown in FIG. 9 and FIG. 10, a semiconductor device SD2 according to the second embodiment has basically the same configuration as the semiconductor device SD1 according to the first embodiment and has the same effects, but is different from the semiconductor device SD1 in that the MIM capacitor element ME includes a sidewall dielectric film SWI. In the following, how the semiconductor device SD2 according to the second embodiment differs mainly from the semiconductor device SD1 according to the first embodiment will be described. In FIG. 9, illustration of the semiconductor substrate SUB, the dielectric film IN, the first lead-out wiring BL, and the first via-plug BV is omitted.

As shown in FIG. 9, the sidewall dielectric film SWI is disposed on the flange portion FL and covers the side end surface of the upper electrode UE and the side end surface MBS of the body portion MB. The sidewall dielectric film SWI is in contact with each of the side end surface MBS of the body portion MB, the upper surface of the flange portion FL, and the dielectric film IN. The sidewall dielectric film SWI is interposed between the dielectric layer IL and the dielectric film IN. As shown in FIG. 10, the sidewall dielectric film SWI is formed so as to surround the entire circumference of the upper electrode UE and the body portion MB of the dielectric layer IL in plan view. A material configuring the sidewall dielectric film SWI may be any material having an electrical dielectric property, but includes, for example, SiO₂. The material configuring the sidewall dielectric film SWI may be the same as the material configuring the dielectric layer IL. The material configuring the sidewall dielectric film SWI may be different from the material configuring the dielectric layer IL.

The manufacturing method of the semiconductor device SD2 has basically the same configuration as the manufacturing method of the semiconductor device SD1, but is different from the manufacturing method of the semiconductor device SD1 in that the manufacturing method of the semiconductor device SD2 includes depositing the first dielectric film so as to cover the upper electrode UE and the dielectric film DF after forming the upper electrode UE and before forming the dielectric layer IL, and that the sidewall dielectric film SWI and the flange portion FL are continuously formed by performing an anisotropic etching process (etch-back process) to the first dielectric film in forming the dielectric layer IL. In the following, how the manufacturing method of the semiconductor device SD2 differs mainly from the manufacturing method of the semiconductor device SD1 will be described.

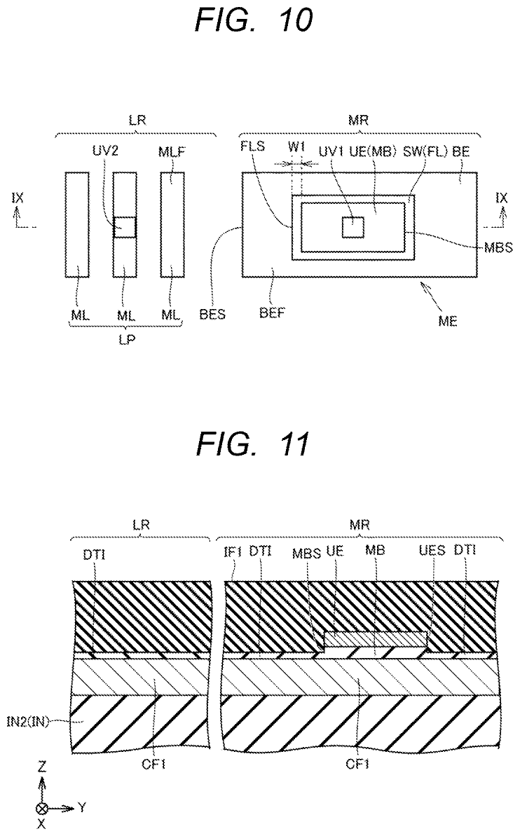

After the upper electrode UE is formed as in the manufacturing method of the semiconductor device SD1, as shown in FIG. 11, a first dielectric film IF1 is formed so as to cover the upper electrode UE and the thin portion DTI of the dielectric film DF. The first dielectric film IF1 covers the side end surface UES of the upper electrode UE and the side end surface MBS of the body portion MB of the dielectric film DF.

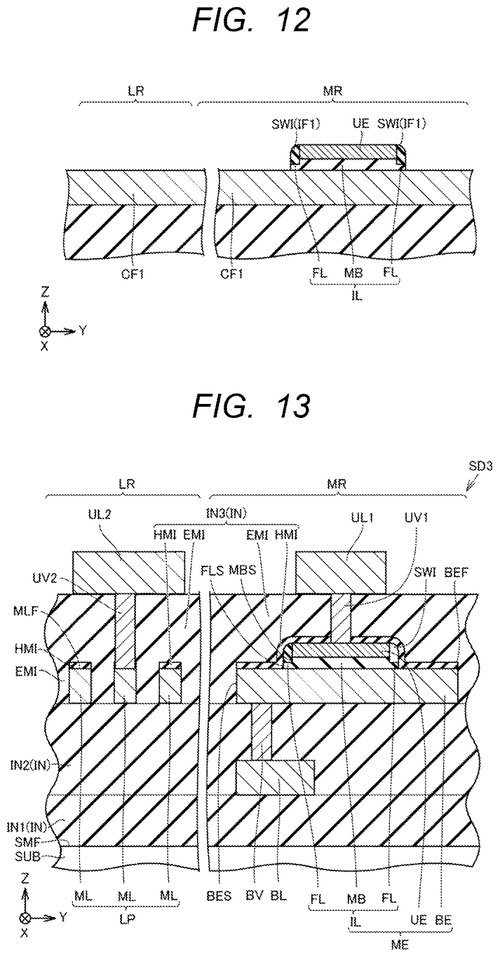

As shown in FIG. 12, after the first dielectric film IF1 forming step, the dielectric layer IL forming step is performed. In this step, an anisotropic etching process is performed to the first dielectric film IF1 to form the sidewall dielectric film SWI from the first dielectric film IF1. Further, the thin portion DTI exposed from the sidewall dielectric film SWI is removed, thereby forming the flange portion FL. When the material configuring the first dielectric film IF1 (sidewall dielectric film SWI) is the same as the material configuring the dielectric layer IL, the first etching process to form the sidewall dielectric film SWI and the second etching process to form the flange portion FL can be performed without interruption under the same conditions. On the other hand, when the material configuring the first dielectric film IF1 (sidewall dielectric film SWI) is different from the material configuring the dielectric layer IL, after the first etching process to form the sidewall dielectric film SWI is completed, the second etching process to form the flange portion FL is performed in different conditions from the first etching process.

Thereafter, the lower electrode BE, the wiring pattern PL, and the like are formed in the same manner as the manufacturing method of the semiconductor device SD1, whereby the semiconductor device SD2 can be manufactured.

In the semiconductor device SD1, since the flange portion FL is formed using photolithography, the second mask MK2 needs to be formed relatively large with respect to the upper electrode UE in view of the alignment accuracy by photolithography. Therefore, the width of the flange portion FL in the semiconductor device SD1 is set relatively wide. On the other hand, in the semiconductor device SD2, the flange portion FL can be formed in a self-aligned manner (in self-alignment) without using photolithography. Therefore, the second mask MK2 does not need to be formed, and therefore, it is not necessary to consider the alignment accuracy by photolithography. Therefore, the width of the flange portion FL in the semiconductor device SD2 can be accurately controlled in accordance with the thickness of the first dielectric film IF1. Therefore, the width of the flange portion FL in the semiconductor device SD2 can be set to be narrower than the width of the flange portion FL in the semiconductor device SD1 as long as the reliability of the MIM capacitor element ME is not impaired.

In the manufacturing method of the semiconductor device SD2, since the flange portion FL is formed by an anisotropic etching process together with the sidewall dielectric film SWI, the second mask MK2 to form the flange portion FL used in the manufacturing method of the semiconductor device SD1 is not required. That is, the manufacturing method of the semiconductor device SD2 eliminates the need for a photomask to form the second mask MK2 by photolithography, which reduces manufacturing costs.

### Third Embodiment

As shown in FIG. 13, a semiconductor device SD3 according to the third embodiment has basically the same configuration as the semiconductor device SD2 according to the second embodiment and has the same effects, but is different from the semiconductor device SD2 in that the third interlayer dielectric film IN3 includes a hard mask dielectric film HMI and a buried dielectric film EMI. In the following, how the semiconductor device SD3 according to the third embodiment differs mainly from the semiconductor device SD2 according to the second embodiment will be described.

The hard mask dielectric film HMI is in contact with the surface of the upper electrode UE and the dielectric layer IL in the MIM region and a portion of the upper surface of the lower electrode BE exposed from the dielectric layer IL, and is in contact with the upper surface of the wiring pattern LP in the wiring region LR. A material configuring the hard mask dielectric film HMI may be any material having a high etching selectivity with respect to the first conductor film CF1 which is a workpiece in the lower electrode BE forming step and the wiring pattern LP forming step, and may include, for example, SiO 2. The thickness of the hard mask dielectric film HMI is set so that the hard mask dielectric film HMI appropriately remains until the processing of the wiring pattern LP and the lower electrode BE is completed, and that the buried dielectric film EMI can be appropriately formed between adjacent wirings MP.

The buried dielectric film EMI is formed on the hard mask dielectric film HMI. The buried dielectric film EMI is formed so as to fill the unevenness formed on the second interlayer dielectric film IN2. The buried dielectric film EMI fills between adjacent wirings ML and the hard mask dielectric film HMI in the wiring region LR. The buried dielectric film EMI is in contact with the side end surface of the wiring pattern LP and the side end surface and the upper surface of the hard mask dielectric film HMI in the wiring region LR. The buried dielectric film EMI covers the periphery of the MIM capacitor element ME in the MIM region MR. The buried dielectric film EMI is in contact with the side end surface BES of the lower electrode BE and the side end surface and the upper surface of the hard mask dielectric film HMI in the MIM region MR. A material configuring the buried dielectric film EMI includes, for example, SiO₂.

The manufacturing method of the semiconductor device SD3 has basically the same configuration as the manufacturing method of the semiconductor device SD2, but is different from the manufacturing method of the semiconductor device SD2 in that the manufacturing method of the semiconductor device SD3 further includes the hard mask dielectric film HMI forming step in the MIM region MR and wiring regions LR after forming the dielectric layer IL, and the first conductor film CF1 forming step using the hard mask dielectric film HMI as a mask. In the following, how the manufacturing method of the semiconductor device SD3 differs mainly from the manufacturing method of the semiconductor device SD2 will be described.

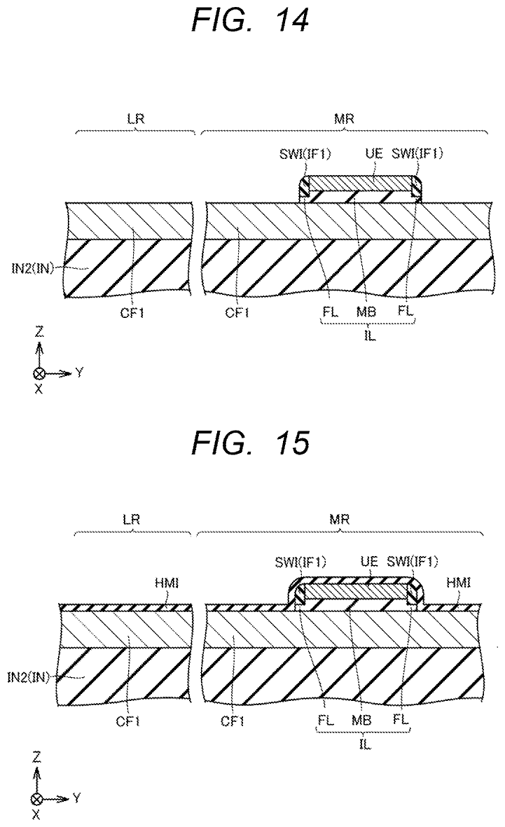

As shown in FIG. 14, after the dielectric layer IL including the sidewall dielectric film SWI and the flange portion FL is formed, as shown in FIG. 15, a second dielectric film IF2 is formed on the entire first conductor film CF1 in the MIM region MR and the wiring region LR. The second dielectric film IF2 covers the upper surface of the first conductive film CF1 and the surface of the MIM capacitor element ME.

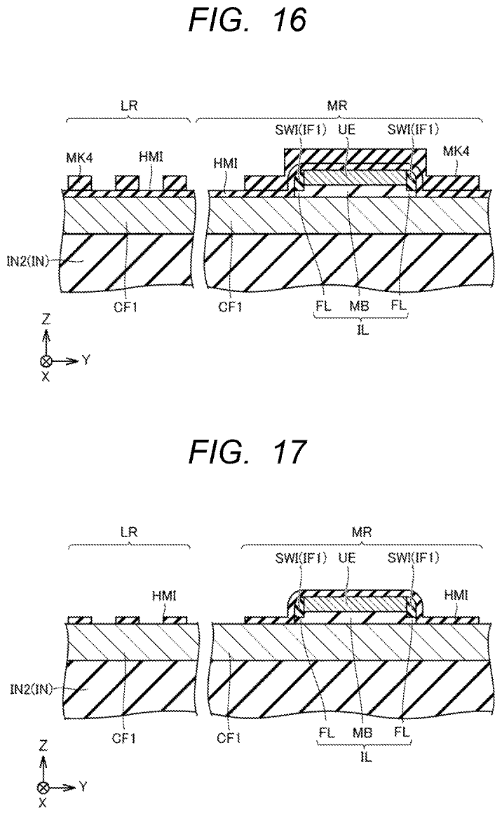

As shown in FIG. 16 and FIG. 17, the hard mask dielectric film HMI is formed from the second dielectric film IF2. Specifically, as shown in FIG. 16, a fourth mask MK4 is formed on a region of the first conductive film CF1 where the lower electrode BE and the wiring pattern LP are to be formed. The fourth mask MK4 is, for example, a resist mask formed by photolithography.

Next, the second dielectric film IF2 is patterned by a dry etching method or the like using the fourth mask MK4. Thus, as shown in FIG. 17, the hard mask dielectric film HMI is formed from the second dielectric film IF2. After the hard mask dielectric film HMI is formed, the fourth mask MK4 is removed.

As shown in FIG. 18, the lower electrode BE and the wiring pattern LP are formed from the first conductor film CF1 by using the hard mask dielectric film HMI. Thus, the lower electrode BE is formed from the first conductor film CF1 in the MIM region MR. At the same time, the wiring pattern LP is formed from the first conductor film CF1 in the wiring region LR. The hard mask dielectric film HMI remains without being removed even after the lower electrode BE and the wiring pattern LP are formed. As a result, the hard mask dielectric film MIM is formed in the MIM region MR so as to cover the surface of the upper electrode UE and the dielectric layer IL of the MIM capacitor element ME and the upper surface of the lower electrode BE of the MIM capacitor element ME. Further, the hard mask dielectric film HMI covering the upper surface of the wiring pattern LP is formed in the wiring region LR.

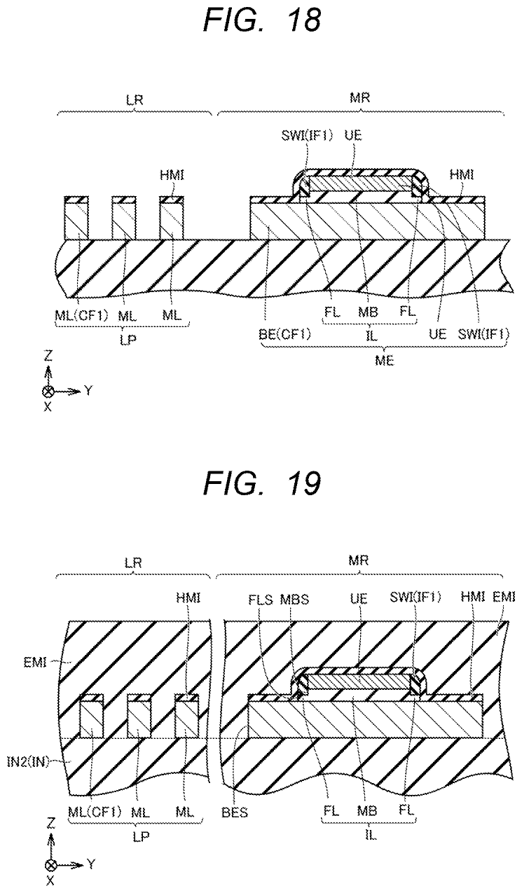

As shown in FIG. 19, the buried dielectric film EMI is formed on the second interlayer dielectric film IN2 in the MIM region MR and the wiring region LR. The buried dielectric film EMI is formed, for example, by removing a part of the dielectric film formed by the HDP-CVD (High Density Plasma Chemical Vapor Deposition) method by the CMP (Chemical Mechanical Polishing) method. The buried dielectric film EMI fills between adjacent wirings ML and the hard mask dielectric film HMI in the wiring region LR. The buried dielectric film EMI fills the periphery of the MIM capacitor element ME in the MIM region MR.

In the manufacturing method of the semiconductor device SD3, since the hard mask dielectric film HMI is used to form the lower electrode BE and the wiring pattern LP, the finer wiring pattern LP can be formed as compared with the semiconductor device SD2 in which the lower electrode BE and the wiring pattern LP are formed using the third mask MK3 made of resist.

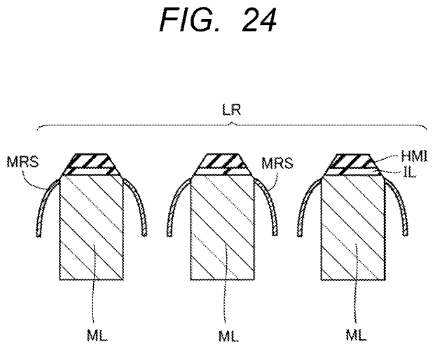

Even when the dielectric film and the conductor film are processed using the hard mask dielectric film in the semiconductor device according to the comparative example including the dielectric film (capacitor dielectric film) remaining on the wiring pattern LP in the wiring region LR, suppressing variation in the total thickness of the remaining film of the dielectric film and the hard mask dielectric film is difficult, and thus miniaturization of the wiring pattern is difficult as compared with the semiconductor device SD3. In the comparative example, when the total thickness of the remaining film of the dielectric film and the hard mask dielectric film increases, the dielectric film filling between adjacent wirings is not properly formed, and voids may be formed in the buried dielectric film. On the other hand, as shown in FIG. 24, if the total thickness of the remaining film of the dielectric film and the hard mask dielectric film is reduced, when the dielectric film filling between adjacent wirings is formed, the upper edge portion of the wiring is exposed, the conductive material (for example, Ti) configuring the exposed portion of the wiring is re-spattered between wirings, deposits MRS made of the conductive material is formed between the wirings ML, and the short-circuit may occur between the wirings MP.

On the other hand, in the semiconductor device SD3, as in the semiconductor device SD1, the wiring pattern LP is formed from the first conductor film CF1 of which the upper surface is exposed in the wiring region LR, and thus the semiconductor device SD3 can be miniaturized as compared with the comparative example.

### MODIFIED EXAMPLE

The semiconductor devices SD1 to SD3 may further include a second hard mask dielectric film HMI2 formed on the upper electrode UE of the MIM capacitor element ME. In the manufacturing methods of the semiconductor devices SD1 to SD3, the second hard mask dielectric film HMI2 may be used instead of the first mask MK1 in the upper electrode UE forming step. In particular, the second hard mask dielectric film HMI2 is suitable for the semiconductor device SD2 and the semiconductor device SD3 in which the MIM capacitor element ME includes the sidewall dielectric film SWI.

A semiconductor device SD4 shown in FIG. 20 has basically the same configuration as the semiconductor device SD2, but is different from the semiconductor device SD2 in that the semiconductor device SD4 includes the second hard mask dielectric film HMI2. The manufacturing method of the semiconductor device SD4 is basically the same as the manufacturing method of the semiconductor device SD2, but is different from the manufacturing method of the semiconductor device SD2 in that the second hard mask dielectric film HMI2 is used instead of the first mask MK1 in the upper electrode UE forming step. In the following, how the semiconductor device SD4 and the manufacturing method of the semiconductor device SD4 differs mainly from the semiconductor device SD2 and the manufacturing method of the semiconductor device SD2 will be described.

The second hard mask dielectric film HMI2 is in contact with the upper surface of the upper electrode UE in the MIM region MR. A material configuring the second hard mask dielectric film HMI2 may be any material having a high etching selectivity with respect to the second conductor film CF2 which is a workpiece in the upper electrode UE forming step and having an electrical dielectric property, and includes, for example, SiO 2. The thickness of the second hard mask dielectric film HMI2 is set so that the second hard mask dielectric film HMI2 appropriately remain until the processing of the upper electrode UE is completed.

The sidewall dielectric film SWI covers the side end surface of the second hard mask dielectric film HMI2, the side end surface of the upper electrode UE, and the side end surface MBS of the body portion MB.

The second via-plug UV1 penetrates through the second hard mask dielectric film HMI2 and the third interlayer dielectric film IN3 (refer to FIG. 1) which are interposed between the upper surface of the upper electrode UE and the lower surface of the first lead-out wiring UL1.

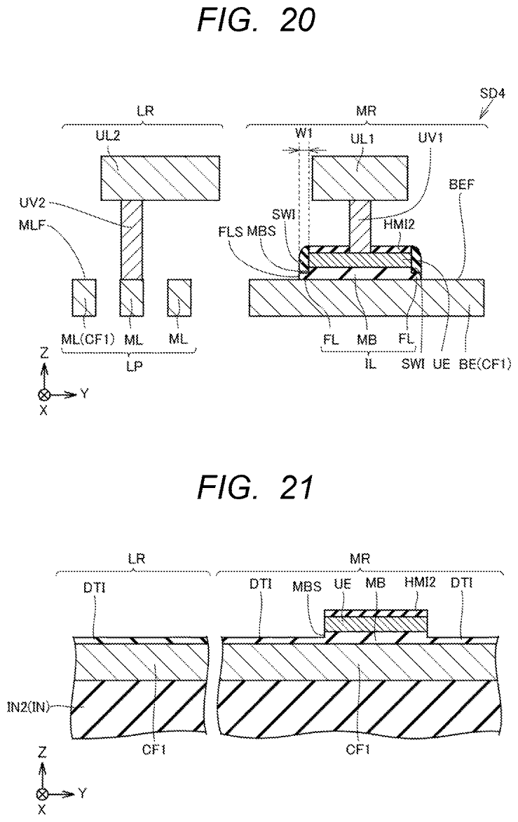

In the manufacturing method of the semiconductor device SD4, as shown in FIG. 21, the second hard mask dielectric film HMI2 is formed on the second conductor film CF2. The second hard mask dielectric film HMI2 is formed on the region of the second conductor film CF2 where the upper electrode UE and the body portion MB are to be formed in the same manner as the hard mask dielectric film HMI described above. Further, the body portion MB and the thin portion DTI thinner than the body portion MB is formed in the dielectric film DF.

As shown in FIG. 22, the first dielectric film IF1 is formed so as to cover the second hard mask dielectric film HMI2, the upper electrode UE, and the thin portion DTI of the dielectric film DF. The first dielectric film IF1 covers the side end surface MHIS of the second hard mask dielectric film HMI2, the side end surface UES of the upper electrode UE, and the side end surface MBS of the body portion MB of the dielectric film DF.

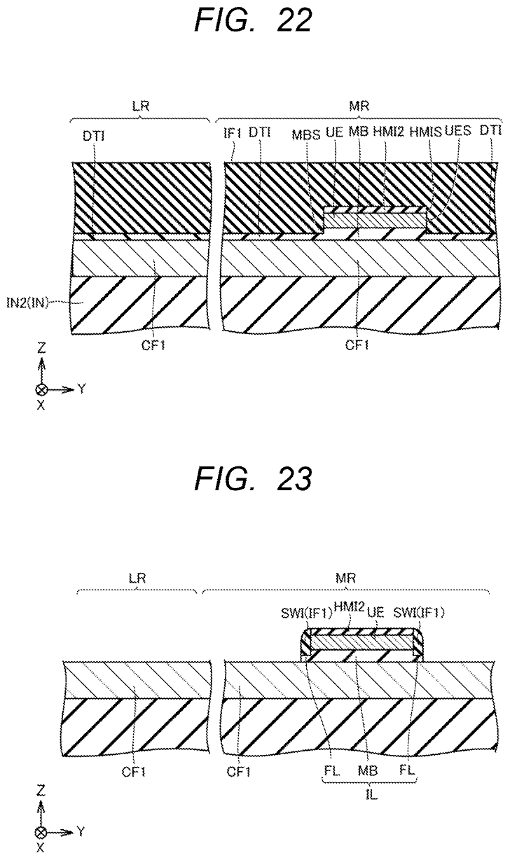

As shown in FIG. 23, an anisotropic etching process is performed to the first dielectric film IF1 to form the sidewall dielectric film SWI from the first dielectric film IF1. Further, the thin portion DTI exposed from the sidewall dielectric film SWI is continuously removed, whereby the flange portion FL is formed. In this step, the upper electrode UE is covered with the second hard mask dielectric film HMI2 and the sidewall dielectric film SWI, and thus is not exposed to the etching process. Thereafter, the lower electrode BE, the wiring pattern PL, and the like are formed in the same manner as the manufacturing method of the semiconductor device SD1, whereby the semiconductor device SD4 can be manufactured.

The effects of the semiconductor device SD4 is explained based on the comparison with the semiconductor device SD2. In the step of forming the sidewall dielectric film SWI in the manufacturing method of the semiconductor device SD2, since the upper surface of the upper electrode UE is exposed during the etching process of the first dielectric film IF1, so that the capacitance value of the MIM capacitor element ME may vary due to etching of the upper surface of the upper electrode UE, particularly, the outer edge portion (shoulder portion) of the upper surface. On the other hand, in the step of forming the sidewall dielectric film SWI in the manufacturing method of the semiconductor device SD4, since the upper electrode UE is covered with the second hard mask dielectric film HMI2 and the first dielectric film IF1, the upper electrode UE is not exposed to the etching process. Therefore, in the semiconductor device SD4, variation in capacitance value of the MIM capacitor element ME can be suppressed.

In the semiconductor devices SD1 to SD4, the dielectric layer IL need not be formed in the wiring region LR. The dielectric layer IL may be formed on the entire upper surface of the lower electrode BE in the MIM region MR. From a different point of view, the entire upper surface BEF of the lower electrode BE may be in contact with the dielectric layer IL. The side end surface FLS of the flange portion FL may be continuous with the side end surface BES of the lower electrode BE in the third direction Z. The semiconductor devices SD1 to SD4 can be manufactured by removing all of the thin portions DTI of the dielectric film DF in at least wiring region LR in the step of forming the dielectric layer IL in the manufacturing method.

In the semiconductor devices SD1 to SD4, as described above, the thickness of the flange portion FL may be equal to the thickness of the body portion MB. In the semiconductor devices SD1 to SD4, the side end surface MBS may not be formed on the body portion MB. In the semiconductor devices SD2 to SD4, the sidewall dielectric film SWI may cover at least the side end surface UES of the upper electrode UE.

Although the invention made by the present inventor has been specifically described based on the embodiment, the present invention is not limited to the embodiment described above, and it is needless to say that various modifications can be made without departing from the gist thereof.

What is claimed is:

1. A method of manufacturing a semiconductor device including a first region where a capacitor element is formed and a second region where a wiring pattern is formed, the method comprising:
depositing a first conductor film, a dielectric film and a second conductor film in this order in the first region and the second region;
selectively removing the second conductor film such that the dielectric film is exposed, forming an upper electrode of the capacitor element from the remaining second conductor film in the first region;
selectively removing the exposed dielectric film, thereby exposing the first conductor film in the second region and forming a dielectric layer having a flange portion remaining so as to protrude outward from a region under the upper electrode in the first region; and
selectively removing the first conductor film, thereby forming a lower electrode of the capacitor element from the first conductor film in the first region and forming the wiring pattern from the first conductor film of which an upper surface is exposed in the second region.

2. The method according to claim 1,
wherein in the forming the dielectric layer, a portion of the first conductor film is exposed from dielectric layer in the first region, and
wherein in the forming the wiring pattern, the lower electrode having a portion exposed from the dielectric layer in plan view is formed.

3. The method according to claim 1,
wherein a shortest distance between a side end surface of the upper electrode and a side end surface of the flange portion is 50 nm or more.

4. The method according to claim 1, comprising:
after the forming the upper electrode and before the forming the dielectric layer, depositing a first dielectric film so as to cover the upper electrode and the dielectric film,
wherein in the forming the dielectric layer, an anisotropic etching process is performed to the first dielectric film to form a sidewall dielectric film covering a side end surface of the upper electrode, and the dielectric film exposed from the upper electrode and from the sidewall dielectric film in plan view is removed to form the flange portion between the sidewall dielectric film and the first conductor film.

5. The method according to claim 4, comprising:
after the forming the dielectric layer, forming a hard mask dielectric film on the first conductor film,
wherein in the forming the wiring pattern, a portion of the first conductor film using the hard mask dielectric film to form the lower electrode and the wiring pattern under the hard mask dielectric film.

6. The method according to claim 5, comprising:
after the forming the lower electrode and the wiring pattern, forming a third dielectric film having an upper surface on the hard mask dielectric film;
forming a via-plug penetrating through the hard mask dielectric film and the third dielectric film; and
forming a third conductor film electrically connected to the via-plug on the upper surface of the third dielectric film.

7. The method according to claim 4, comprising:
after the depositing the first conductor film, the dielectric film and the second conductor film in this order, forming a second hard mask dielectric film on the second conductor film,
wherein in the forming the upper electrode, the second conductor film exposed from the second hard mask dielectric film is selectively removed to form an upper electrode of the capacitor element from the second conductor film under the second hard mask dielectric film in the first region,
wherein in the depositing the first dielectric film, the first dielectric film is deposited so as to cover the second hard mask dielectric film, the upper electrode and the dielectric film, and
wherein in the forming the dielectric layer, an anisotropic etching process is performed to the first dielectric film to form the sidewall dielectric film covering a side end surface of the second hard mask dielectric film and the side end surface of the upper electrode.

8. A semiconductor device comprising:
a MIM capacitor element;
a wiring pattern; and
an interlayer dielectric film formed on the MIM capacitor element and the wiring pattern,
wherein the MIM capacitor element includes:
a lower electrode;
a dielectric layer formed on the lower electrode; and
an upper electrode formed on the dielectric layer,
wherein the dielectric layer has a flange portion remaining so as to protrude outward from a region under the upper electrode, and
wherein an upper surface of the wiring pattern is in contact with the interlayer dielectric film.

9. The semiconductor device according to claim 8,
wherein a portion of an upper surface of the lower electrode is in contact with the interlayer dielectric film.

10. The semiconductor device according to claim 8,
wherein a shortest distance between a side end surface of the upper electrode and a side end surface of the flange portion is 50 nm or more.

11. The semiconductor device according to claim 8,
wherein the MIM capacitor element includes a sidewall dielectric film, and
wherein the sidewall dielectric film is disposed on the flange portion and covers a side end surface of the upper electrode.

12. The semiconductor device according to claim 8,
wherein the interlayer dielectric film includes a hard mask dielectric film being in contact with the upper surface of the wiring pattern and a surface of the MIM capacitor element.
